(19) United States
(12) Patent Application Publication
(10) Pub. No.: US 2024/0292525 A1
(43) Pub. Date: Aug. 29, 2024

(54) Flexible printed circuit

(71) Applicant: AAC Microtech (Changzhou) Co., Ltd., Changzhou (CN)

(72) Inventors: Zhigao Lu, Changzhou (CN); Guohui Chen, Changzhou (CN)

(21) Appl. No.: 18/327,871

(22) Filed: Jun. 1, 2023

Related U.S. Application Data
(63) Continuation of application No. PCT/CN2023/090910, filed on Apr. 26, 2023.

(30) Foreign Application Priority Data
Feb. 23, 2023 (CN) 202320306455.0

(51) Int. Cl. H05K 1/02; H05K 1/11

(52) U.S. Cl. CPC H05K 1/0277; H05K 1/115; H05K 1/09; H05K 2201/0154

(57) ABSTRACT

The present disclosure discloses a circuit board including an intermediate layer and two protective layers wrapped on opposite sides of the intermediate layer, the intermediate layer including a substrate layer in the middle, the substrate layer having a through hole, wherein the intermediate layer further includes a first line layer and a second line layer respectively provided on opposite sides of the substrate layer, a first overlay layer and a second overlay layer respectively provided on opposite sides of the substrate layer and a guide member embedded in the through hole and connecting the first and second line layers, the first line layer being embedded in the first overlay layer and the second line layer being embedded in the second overlay layer. The flexible printed circuit of the present disclosure can avoid the risk of dry film breakage when laminating the overlay film and hole breakage defect when etching.

### FIELD OF THE PRESENT DISCLOSURE

The present disclosure relates to circuit boards, especially relates to a flexible printed circuit.

### DESCRIPTION OF RELATED ART

Flexible printed circuits, also known as “flex boards,” are printed circuits made from flexible insulating substrates. Flexible circuits offer excellent electrical properties to meet the design needs of smaller and higher density installations, as well as help reduce assembly processes and increase reliability. Flexible printed circuits can be freely bent, wound, folded, and withstand millions of dynamic bends without damage to the wire, and can be arranged in accordance with the requirements of spatial layout, and moved and expanded in three dimensions at will, thus achieving the integration of component assembly and wire connection.

Flexible printed circuits can be classified by single-sided, double-sided and multilayer boards, flexible circuit boards, especially double-sided and multilayer boards are usually designed for optional plating through-hole guide, the use of double-sided copper foil drilling after plating through-hole and forming a hole ring, however, the use of this method of preparation of flexible circuit boards within the copper plating and the original copper thickness difference, copper plating layer raised on the original copper, the appearance of the hole ring is raised, thickness difference in the dry film easy to break the film when pressed together, and etching is easy to lead to hole broken bad, when press-laminated the overlay film, it is difficult to fill the rubber layer at the thickness difference and easy to form bubble cavities, which is difficult to meet the production needs.

Therefore, it is necessary to provide a new kind of flexible circuit board.

### SUMMARY OF THE INVENTION

The present disclosure provides a flexible printed circuit capable of solving the above-mentioned series of problems caused by the thickness difference of the copper layer in the flexible printed circuit in the prior art.

The flexible printed circuit comprising an intermediate layer and two protective layers wrapped on opposite sides of the intermediate layer, the intermediate layer comprising a substrate layer in the middle, the substrate layer having a through hole, the intermediate layer further comprises a first line layer and a second line layer respectively provided on opposite sides of the substrate layer, a first overlay layer and a second overlay layer respectively provided on opposite sides of the substrate layer and a guide member embedded in the through hole and connecting the first and second line layers, the first line layer being embedded in the first overlay layer and the second line layer being embedded in the second overlay layer.

Further, the surfaces of the first line layer and the first overlay layer are flush on the side away from the substrate layer, and the surfaces of the second line layer and the second overlay layer are flush on the side away from the substrate layer.

Further, the protective layer comprises a adhesive layer attached to the outer side of the intermediate layer, and an insulating layer located on the side of the adhesive layer away from the intermediate layer.

Further, both the substrate layer and the insulating layer are PI materials.

Further, the first overlay layer and the second overlay layer are light-sensitive overlay films.

Further, the first line layer, the second line layer and the guide member are made of copper.

Further, the first line layer and the second line layer are prepared by means of PI metallization, copper plating and copper reduction on opposite sides of the substrate layer in turn.

In the flexible printed circuit of the present disclosure, the intermediate layer includes a substrate layer and a first overlay layer and a second overlay layer affixed to opposite sides of the substrate layer, the first line layer being embedded in the first overlay layer and the second line layer being embedded in the second overlay layer, two protective layers are laminated on the side of the first overlay layer away from the substrate layer and the side of the second overlay layer away from the substrate layer. A guide member is provided in the through hole of the substrate layer, the guide member connecting the first line layer and the second line layer as one, capable of ensuring line conduction between the first line layer and the second line layer; There is no height difference in the connection between the guide member and the line layer, thus making the surface of the overlay layer flat and avoiding the risk of dry film breakage when laminating the overlay film and hole breakage when etching.

### BRIEF DESCRIPTION OF THE DRAWINGS

The present disclosure will hereinafter be described in detail with reference to an exemplary embodiment. To make the technical problems to be solved, technical solutions and beneficial effects of present disclosure more apparent, the present disclosure is described in further detail together with the figures and the embodiment. It should be understood the specific embodiment described hereby is only to explain this disclosure, not intended to limit this disclosure.

FIG. 1 is a cross-sectional view of the flexible printed circuit of the present disclosure.

FIG. 2 is a process flow diagram of the flexible printed circuit of the present disclosure in cross-sectional view.

FIG. 3 is a process flow diagram of the flexible printed circuit of the present disclosure in top view.

### DETAILED DESCRIPTION OF THE EXEMPLARY EMBODIMENT

The present disclosure will hereinafter be described in detail with reference to an exemplary embodiment. To make the technical problems to be solved, technical solutions and beneficial effects of the present disclosure more apparent, the present disclosure is described in further detail together with the figure and the embodiment. It should be understood the specific embodiment described hereby is only to explain the disclosure, not intended to limit the disclosure.

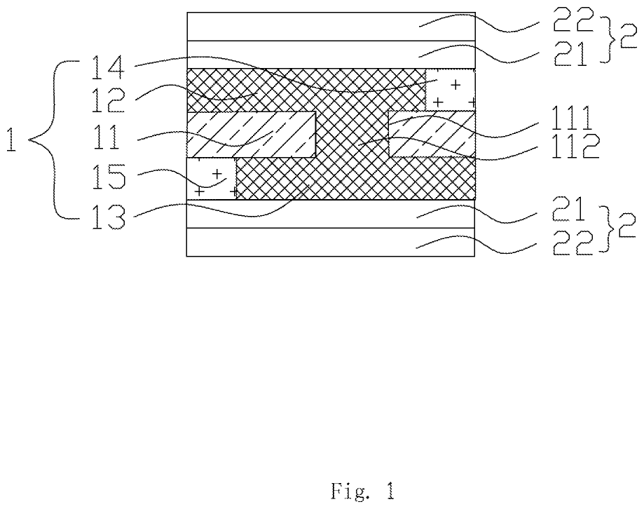

Please refer to FIGS. 1-3, a flexible printed circuit 100 comprising: an intermediate layer 1 and two protective layers 2 wrapped on opposite sides of the intermediate layer 1, the intermediate layer 1 comprising a substrate layer 11 in the middle, the substrate layer 11 having a through hole 111, wherein the intermediate layer 1 further comprises a first line layer 12 and a second line layer 13 respectively provided on opposite sides of the substrate layer 11, a first overlay layer 14 and a second overlay layer 15 respectively provided on opposite sides of the substrate layer 11 and a guide member 112 embedded in the through hole 111 and connecting the first line layer 12 and second line layer 13, the first line layer 12 being embedded in the first overlay layer 14 and the second line layer 13 being embedded in the second overlay layer 15.

In the present embodiment, the intermediate layer 1 comprises the substrate layer 11 and a first overlay layer 14 and a second overlay layer 15 affixed to opposite sides of the substrate layer 11, the first line layer 12 being embedded in the first overlay layer 12 and the second line layer 13 being embedded in the second overlay layer 15, two protective layers 2 are laminated on the side of the first overlay layer 14 away from the substrate layer 11 and the side of the second overlay layer 15 away from the substrate layer 11. A guide member 112 is provided in the through hole 111 of the substrate layer 11, the guide member 112 connecting the first line layer 12 and the second line layer 13 as one, capable of ensuring line conduction between the first line layer 12 and the second line layer 13; There is no height difference in the connection between the guide member 112 and the line layer, thus making the surface of the overlay layer flat and avoiding the risk of dry film breakage when laminating the overlay film and hole breakage when etching.

In the present embodiment, the protective layer 2 comprises a adhesive layer 21 attached to the outer side of the intermediate layer 1, and an insulating layer 22 located on the side of the adhesive layer 21 away from the intermediate layer 1. A side of the first overlay 14 away from the substrate layer and a side of the second overlay 15 away from the substrate layer 11 are each connected to the corresponding adhesive layer 21. The insulating layer 22 is firmly integrated with the intermediate layer 1 as one by means of the adhesive layer 21. In this embodiment, the material of the adhesive layer 21 can be solvent-based high-elastic polyurethane, water-based high-elastic polyurethane, UV protective adhesive, etc., with soft, good bending, good wear resistance, etc., not easy to scratch, not easy to produce creases.

In the present embodiment, both the substrate layer 11 and the insulating layer 22 are PI materials. The thickness of the substrate layer 11 can be 0.0127 to 0.127 mm. PI is polyimide, which is not only resistant to high temperature and abrasion, but also has excellent insulating properties. In some other embodiments, polyester (PET), polytetrafluoroethylene (PTFE), etc. can be used as the material for the substrate layer 11.

In the present embodiment, the first overlay layer 14 and the second overlay layer 15 are light-sensitive overlay films. The light-sensitive overlay film has excellent solder resist and reflective effects. The light-sensitive overlay film is used to fix the first line layer 12 and the second line layer 13 on both sides of the substrate layer 11 respectively, which is convenient for protecting the formed line pattern.

In the present embodiment, the surfaces of the first line layer 12 and the first overlay layer 14 are flush on the side away from the substrate layer 11, and the surfaces of the second line layer 13 and the second overlay layer 14 are flush on the side away from the substrate layer 11. The thickness of the first line layer 12, the first overlay layer 14, the second line layer 13 and the second overlay layer 15 are equal, making the surface of the intermediate layer 1 flat and easier to carry out the filling of the adhesive layer, which can effectively avoid the generation of bubble cavities when filling the glue.

In the present embodiment, the first line layer 12, the second line 13 layer and the guide member 112 are made of copper. The guide member 112 is in the form of a regular cylindrical shape, filled in the through hole 111, and the guide member 112 is connected to the first line layer 12 and the second line layer 13. The copper conductor is not only soft but also has excellent electrical conductivity, thus ensuring the line conduction between the first line layer 12 and the second line layer 13. It will be appreciated that in some other embodiments, metals such as gold or silver can also be used as materials for the first line layer 12, the second line layer 13, and the guide member 112.

In the present embodiment, the first line layer 12 and the second line layer 13 are prepared by means of PI metallization, copper plating and copper reduction on opposite sides of the substrate layer 11 in turn. The first line layer 12 and the second line layer 13 are metal layers covering the surface of the substrate layer 11.

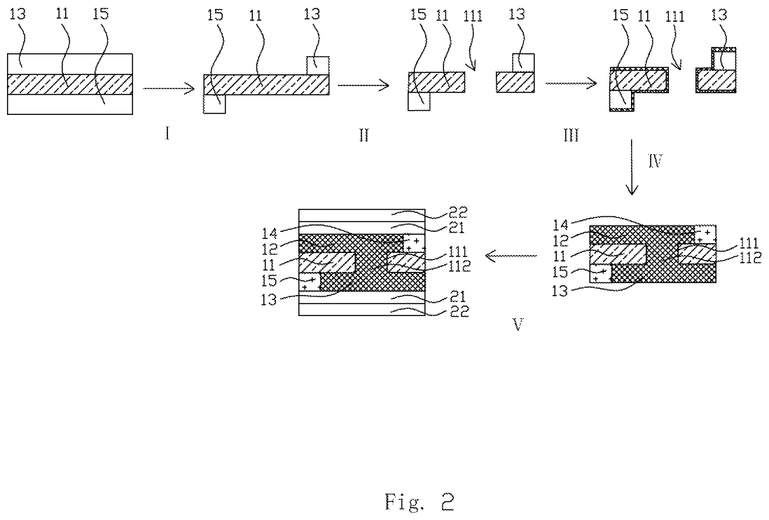

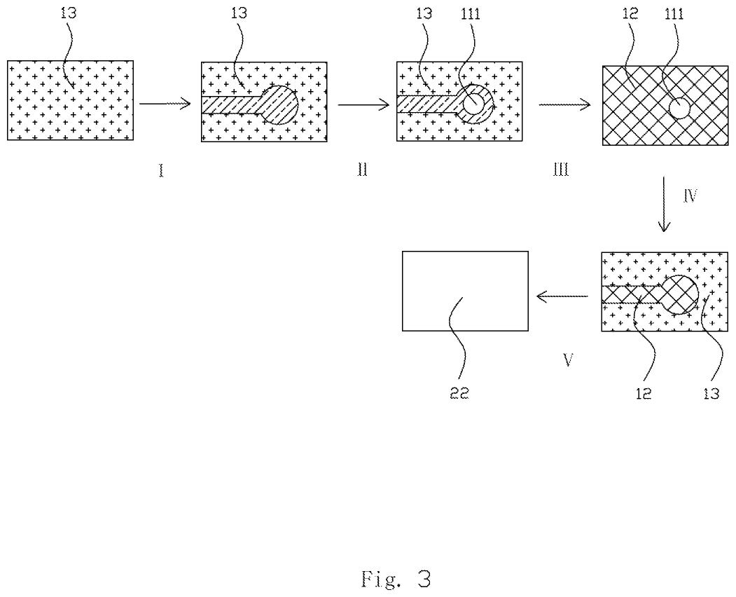

As shown in FIGS. 2 and 3, in this embodiment, the flexible printed circuit may be prepared using the following process steps:

Step I: Provide the initial material of the substrate layer 11 covered with the light-sensitive overlay film on both sides, expose and develop the light-sensitive overlay film to obtain the pattern of the first line layer 12 and the second line layer 13, which is used to form the first line layer 12 and the second line layer 13, where the position where the through hole 111 needs to be opened in the substrate layer is located within the pattern.

Step II: Drilling the holes in the substrate layer 11 to obtain the through hole 111, which can be drilled by laser drilling, CNC drilling or punching at the corresponding position of the substrate layer 11, and the cross section of the through hole 111 is round. The cross-section of the through hole 111 can also be triangular, quadrilateral, etc.

Step III. Perform PI metallization treatment. So that the outer side of the light-sensitive overlay film, the inner wall of the through hole 111 and the exposed areas on both sides of the substrate layer 11 are uniformly covered by a metal layer, which is made of copper.

Step IV. Copper plating and copper reduction is performed. Copper is plated on the outer side of the metal layer formed by PI metallization to obtain a thickened metal layer, wherein the plating process fills the entire through hole 111 to form the guide member 112. By reducing copper on the metal layer obtained after copper plating on both sides of the substrate layer, the line pattern on it is revealed, forming a first line layer 12 flush with the surface of the side of the first overlay layer 14 away from the substrate layer 11, and forming a second line layer 13 flush with the surface of the side of the second overlay layer 15 away from the substrate layer 11.

Step V. Apply protective layer 2 and use glue to bond PI material (material of insulation layer 22) to each side of intermediate layer 1, and wait for the glue to cure (form adhesive layer 21) to obtain the desired flexible printed circuit.

It is to be understood, however, that even though numerous characteristics and advantages of the present exemplary embodiments have been set forth in the foregoing description, together with details of the structures and functions of the embodiments, the disclosure is illustrative only, and changes may be made in detail, especially in matters of shape, size, and arrangement of parts within the principles of the invention to the full extent indicated by the broad general meaning of the terms where the appended claims are expressed.

What is claimed is:

1. A flexible printed circuit comprising: an intermediate layer and two protective layers wrapped on opposite sides of the intermediate layer, the intermediate layer comprising a substrate layer in the middle, the substrate layer having a through hole, wherein the intermediate layer further comprises a first line layer and a second line layer respectively provided on opposite sides of the substrate layer, a first overlay layer and a second overlay layer respectively provided on opposite sides of the substrate layer and a guide member embedded in the through hole and connecting the first and second line layers, the first line layer being embedded in the first overlay layer and the second line layer being embedded in the second overlay layer.

2. The flexible printed circuit as described in claim 1, wherein the surfaces of the first line layer and the first overlay layer are flush on the side away from the substrate layer, and the surfaces of the second line layer and the second overlay layer are flush on the side away from the substrate layer.

3. The flexible printed circuit as described in claim 1, wherein the protective layer comprises a adhesive layer attached to the outer side of the intermediate layer, and an insulating layer located on the side of the adhesive layer away from the intermediate layer.

4. The flexible printed circuit as described in claim 3, wherein both the substrate layer and the insulating layer are PI materials.

5. The flexible printed circuit as described in claim 1, wherein the first overlay layer and the second overlay layer are light-sensitive overlay films.

6. The flexible printed circuit as described in claim 1, wherein the first line layer, the second line layer and the guide member are made of copper.

7. The flexible printed circuit as described in claim 6, wherein the first line layer and the second line layer are prepared by means of PI metallization, copper plating and copper reduction on opposite sides of the substrate layer in turn.
